(19) United States
(12) Patent Application Publication
(10) Pub. No.: US 2026/0010078 A1
(43) Pub. Date: Jan. 8, 2026

(54) LIGHT SOURCE APPARATUS

(71) Applicant: Lasertec Corporation, Yokohama (JP)

(72) Inventors: Junya KAWAGUCHI, Yokohama-shi (JP); Takahide TAKAMATSU, Yokohama-shi (JP); Masayasu NISHIZAWA, Yokohama-shi (JP); Masaki INOUE, Yokohama-shi (JP)

(21) Appl. No.: 19/256,860

(22) Filed: Jul. 1, 2025

(30) Foreign Application Priority Data
Jul. 4, 2024 (JP) 2024-108194

(51) Int. Cl. G03F 7/00

(52) U.S. Cl. CPC G03F 7/70033; G03F 7/70916; G03F 7/70933; G03F 7/70983

(57) ABSTRACT

A light source apparatus according to the present embodiment includes: an optical path tube configured to connect a space on a side at which a mirror is disposed and a space on a side at which a plasma forming area is disposed, the mirror being configured to extract light produced by plasma; and a filter disposed so as to cover the optical path tube and configured to transmit the light produced by the plasma. The optical path tube is provided with a gas intake part configured to take gas into the optical path tube, the gas intake part being provided on the side at which the plasma forming area is disposed relative to the filter. The optical path tube includes a first outlet and a second outlet configured to guide the gas outside of the optical path tube.

### INCORPORATION BY REFERENCE

This application is based upon and claims the benefit of priority from Japanese patent application No. 2024-108194, filed on Jul. 4, 2024, the disclosure of which is incorporated herein in its entirety by reference for all purposes.

### BACKGROUND

The present disclosure relates to a light source apparatus.

Japanese Patent No. 6681890 discloses an optical path tube that ejects gas against debris from plasma that generates extreme ultraviolet (EUV) light.

### SUMMARY

When the gas in the optical path tube does not flow smoothly, a concern is that the debris cannot be sufficiently suppressed from adhering to optical members, filters and the like, or that the gas accumulates in the optical path tube. This causes a decrease in the amount of EUV light.

The present disclosure is devised in view of such a problem, and provides a light source apparatus that suppresses a decrease in the amount of EUV light.

A light source apparatus according to an aspect of the present embodiment includes:
an optical path tube configured to connect a space on a side at which a mirror is disposed and a space on a side at which a plasma forming area is disposed, the mirror being configured to extract light produced by plasma; and
a filter disposed in the optical path tube and configured to transmit light within at least one wavelength band selected from the light generated by the plasma, in which
the optical path tube is provided with at least one gas intake part configured to take gas into the optical path tube, the at least one gas intake part being provided on the side at which the plasma forming area is disposed relative to the filter,
the optical path tube includes a first outlet and at least one second outlet configured to guide the gas outside of the optical path tube,
the at least one second outlet is provided on the side at which the plasma forming area is disposed relative to the at least one gas intake part, and on the side at which the mirror is disposed relative to the first outlet,
the first outlet discharges the gas on the side at which the plasma forming area is disposed relative to a cover disposed between the plasma forming area and the mirror, and
the at least one second outlet discharges the gas on the side at which the mirror is disposed relative to the cover, and is provided around an outer circumference of the optical path tube.

According to the present disclosure, a light source apparatus can be provided that suppresses a decrease in the amount of EUV light.

The above and other objects, features and advantages of the present disclosure will become more fully understood from the detailed description given hereinbelow and the accompanying drawings.

### BRIEF DESCRIPTION OF DRAWINGS

FIG. 1 is a cross-sectional diagram exemplifying a light source apparatus according to Embodiment 1;

FIG. 2 is a cross-sectional diagram exemplifying a light source apparatus according to Embodiment 2; and

FIG. 3 is a cross-sectional diagram exemplifying a light source apparatus according to Embodiment 3.

### DESCRIPTION OF EMBODIMENTS

Hereinafter, embodiments according to the present disclosure will be described with reference to the drawings. The following description is intended to show suitable embodiments of the present disclosure, and the scope of the present disclosure is not limited to the following embodiments. In the following description, identical reference signs indicate substantially the same subject matter.

### Embodiment 1

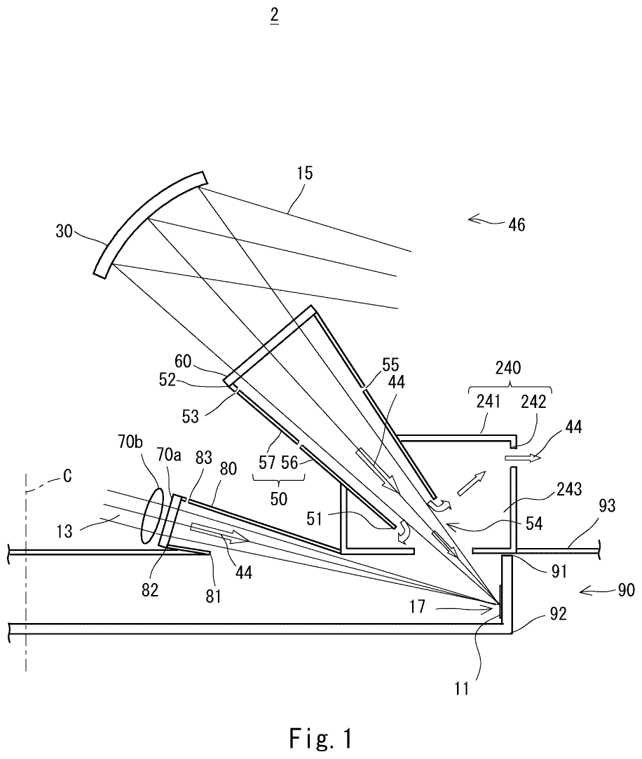

A light source apparatus according to Embodiment 1 will be described. FIG. 1 is a cross-sectional diagram exemplifying a light source apparatus 2 according to Embodiment 1. As shown in FIG. 1, the light source apparatus 2 includes a crucible 90, a target material 11, a debris shield 93, an exhaust case 240, a collector mirror 30, an optical path tube 50, a filter 60, an optical path tube 80, and a transmissive member 70.

The crucible 90 has a central axis C. The crucible 90 rotates about the central axis C as a rotation axis. The crucible 90 is cylinder-shaped, and has one end 91 that is open and another end 92 that is closed. The crucible 90 is heated so that the target material 11 melts on an inner surface.

The target material 11 is a liquid and is disposed in an interior of the crucible 90. The target material 11 spreads out on an inner circumferential surface of the crucible 90 through a centrifugal force caused by the rotation of the crucible 90. In this way, the target material 11 is formed by the liquid target material 11 being spread out on the inner circumferential surface of the crucible 90.

The target material 11 generates EUV light 15 as well as plasma, by being irradiated with a laser beam 13. The laser beam 13 is, for example, a laser beam including infrared (IR) light. The target material 11 may include lithium (Li) or xenon (Xe), and is not limited to tin (Sn), as long as the target material 11 generates the EUV light 15 as well as the plasma by being irradiated with the laser beam 13.

The one end 91 that is open of the crucible 90 is covered by the debris shield 93. The one end 91 of the crucible 90 and the debris shield 93 are separated so as not to affect the rotation of the crucible 90. A portion of the debris shield 93 opposite an irradiation position 17 of the laser beam 13 on the target material 11 is open.

The exhaust case 240 includes an outer cover 241 and an outlet 242. The outer cover 241 is also simply referred to as a cover. The outer cover 241 is disposed between the target material 11 and the collector mirror 30. The outer cover 241 may cover the debris shield 93. In other words, the exhaust case 240 may be disposed on a side at which the one end 91 of the crucible 90 that is open is disposed.

The outer cover 241 may constitute part of a casing of the exhaust case 240. For example, when the casing of the exhaust case 240 includes a top plate on a side at which the collector mirror 30 is disposed, a bottom plate on a side at which a plasma forming area is disposed, and side plates disposed between the top plate and the bottom plate, the top plate or both the top and the side plates constitute the outer cover 241. Alternatively, the debris shield 93 may constitute the bottom plate of the casing.

The casing of the exhaust case 240 is rectangle-shaped with an opening at a bottom. A lower end of the outer cover 241 may be connected to the debris shield 93. An interior of the exhaust case 240 may include a region to which impurities included in purge gas 44 to be described below adhere. A plurality of dividers may be provided in the exhaust case 240 for complicating a flow path of the purge gas 44. The region may be provided with a trap or a vane for adhering impurities.

The outlet 242 communicates with an exhaust space 243 formed on a side at which the plasma forming area is disposed relative to the outer cover 241, that is, on a side at which the target material 11 is disposed. The purge gas 44 is discharged into the exhaust space 243 from a first outlet 54 to be described below. The purge gas 44 with a reduced concentration of impurities is discharged from the outlet 242. The outlet 242 may be referred to as a third outlet. The gas 44 discharged from the first outlet 54 is discharged from the third outlet (242) after passing through the region in the exhaust case 240 where impurities adhere.

The collector mirror 30 reflects the EUV light 15 generated by irradiating the target material 11 with the laser beam 13. The collector mirror 30 is also simply referred to as a mirror. The collector mirror 30, for example, reflects the EUV light 15 to an illumination optical system of an inspection apparatus. This allows the inspection apparatus to use the EUV light 15 as inspection light. Note that the collector mirror 30 may reflect the EUV light 15 to another optical apparatus such as an exposure apparatus, not limited to the inspection apparatus.

The optical path tube 50 connects the exhaust space 243 to be described below on the side at which the plasma forming area is disposed and an optical path space 46 on the side at which the collector mirror 30 is disposed. The optical path tube 50 may, for example, be disposed between the plasma forming area and the collector mirror 30.

The optical path tube 50 has a cone-shaped portion or a truncated cone-shaped portion with a hollow interior, but is not limited thereto. For example, the optical path tube 50 may include a portion of which diameter does not gradually increase from an opening at one end 51 toward an opening at another end 52. To be specific, the optical path tube 50 is tube-shaped, and has the one end 51 that is open and the other end 52 that is open. If the optical path tube 50 is tube-shaped with a diameter of the opening at the other end 52 being greater than a diameter of the opening at the one end 51, the optical path tube 50 may include a portion that is not cone-shaped or truncated cone-shaped. The optical path tube 50 may be tube-shaped increasing in diameter from the opening at the one end 51 toward the opening at the other end 52.

The one end 51 of the optical path tube 50 is opposite the target material 11. The one end 51 of the optical path tube 50 may protrude into a space on the side at which the plasma forming area is disposed relative to the outer cover 241. That is, the optical path tube 50 may be disposed so as to pass through the outer cover 241. Alternatively, the one end 51 of the optical path tube 50 may be connected to the outer cover 241.

The other end 52 of the optical path tube 50 protrudes into a space on the side at which the collector mirror 30 is disposed relative to the outer cover 241. The other end 52 of the optical path tube 50 may be disposed so as to be opposite the collector mirror 30. Alternatively, the collector mirror 30 may be disposed in an interior of the optical path tube 50. In this case, the optical path tube 50 may include an opening in a portion through which reflected light from the collector mirror 30 passes. Alternatively, a transmissive member may be fitted into a portion through which the reflected light passes. The outer cover 241 and the debris shield 93 separate the exhaust space 243 where the plasma forming area is located and the optical path space 46 where the collector mirror 30 is disposed. The optical path space 46 may be maintained in a high-vacuum state by an exhaust pump such as a vacuum pump.

A gas intake part 53 of the optical path tube 50 is provided in the optical path tube 50 on the side at which the collector mirror 30 is disposed relative to the outer cover 241. The purge gas 44 taken in from the gas intake part 53 is ejected from the one end 51 of the optical path tube 50 toward the target material 11. Note that part of the purge gas 44 is also discharged from a second outlet 55 to be described below. At least part of the purge gas 44 may be blown onto the filter 60. The purge gas 44 discharged from the one end 51 of the optical path tube 50 may be discharged from the outlet 242 via the exhaust space 243.

The purge gas 44 includes inert gas or the like. The purge gas 44 may, for example, include at least one of argon (Ar), helium (He), nitrogen (N₂), and hydrogen (H₂), or may include any other gas.

The optical path tube 50 includes the first outlet 54 and the second outlet 55 configured to guide the purge gas 44 out of the optical path tube 50. The first outlet 54 may, for example, be an opening on a side at which the one end 51 of the optical path tube 50 is disposed, but may also be provided in a lateral surface of the optical path tube 50. The first outlet 54 discharges the purge gas 44 inside of the exhaust case 240, that is, on the side at which the plasma forming area is disposed relative to the outer cover 241. Part of the purge gas 44 discharged from the first outlet 54 flows from an opening in the bottom plate of the casing of the exhaust case 240 toward the target material 11, and part of the purge gas 44 flows toward the outlet 242.

The second outlet 55 is provided on the side at which the plasma forming area is disposed relative to the gas intake part 53, and on the side at which the collector mirror 30 is disposed relative to the first outlet 54. The second outlet 55 discharges the purge gas 44 outside of the exhaust case 240, that is, on the side at which the collector mirror 30 is disposed relative to the outer cover 241. The second outlet 55 is provided at a predetermined distance away from the gas intake part 53 along a direction of extension of the optical path tube 50 so that the purge gas 44 travels a fixed distance from the gas intake part 53 to the one end 51. For example, the second outlet 55 may be provided midway between the gas intake part 53 and the one end 51. This allows a uniform flow across an entire cross-section of the optical path tube 50 by the purge gas 44 taken in from the gas intake part 53 to be produced over a comparatively long distance.

The optical path tube 50 may include an optical path tube 56 having the one end 51 and an optical path tube 57 having the other end 52. In this case, the second outlet 55 is provided at a connection point between the optical path tube 56 and the optical path tube 57. For example, when a plurality of protrusions protruding toward the optical path tube 57 are provided at one end of the optical path tube 56 on the side at which the collector mirror 30 is disposed, the second outlet 55 is formed by connecting the optical path tube 56 and the optical path tube 57. A projection may be provided on a side at which the optical path tube 57 is disposed. At least one of the optical path tube 56 and 57 may include a bellows tube. In this case, a length of the optical path tube 50 can be maintained constant while changing a height of the above protrusions, that is, while changing a size of the second outlet 55.

The optical path tube 50 may be temperature-adjusted by a temperature adjustment means such as a heater, a cooler, or a heat sink (not show in the drawing) so that the optical path tube 50 and/or an internal atmosphere thereof is within a predetermined temperature range. For example, the optical path tube 50 is temperature-adjusted by a heat sink so that the internal atmosphere thereof is equal to or lower than a melting point of the target material 11. In this way, by adjusting the temperature of the optical path tube 50 and/or the internal atmosphere thereof to a lower temperature, an intake amount of the purge gas 44 can be increased while suppressing an increase in pressure in the interior of the optical path tube 50. The optical path tube 50 may be temperature-adjusted by the temperature adjustment means so that the optical path tube 50 and/or the internal atmosphere thereof has a temperature difference from the second outlet 55 to the side at which the one end 51 is disposed and from the second outlet 55 to a side at which the other end 52 is disposed. For example, the flow of the purge gas 44 can be made more favorable by temperature-adjusting the optical path tube 50 and/or the internal atmosphere thereof so that the temperature from the second outlet 55 to the side at which the one end 51 is disposed is lower than the temperature from the second outlet 55 to the side at which the other end 52 is disposed.

The filter 60 is disposed at the optical path tube 50. The filter 60 may, for example, be disposed at the other end 52 of the optical path tube 50, but may also be disposed in the interior of the optical path tube 50. The filter 60 transmits the EUV light 15. The filter 60 transmit light within at least one wavelength band selected from the light generated by the plasma. The filter 60 has a composition to suppress transmitting the purge gas 44, such as having a pore or mesh structure finer than molecules of the purge gas 44. In addition to an application to prevent debris from scattering toward the side at which the collector mirror 30 is disposed, the filter 60 may be provided for an application to prevent light of a wavelength other than a desired wavelength from reaching the side at which the collector mirror 30 is disposed.

The optical path tube 80 connects the exhaust space 243 and the optical path space 46. The optical path tube 80 may be disposed between the plasma forming area and the transmissive member 70.

The optical path tube 80 is cone-shaped or truncated cone-shaped with a hollow interior, but is not limited thereto. For example, the optical path tube 80 may include a portion of which diameter does not gradually increase from an opening at one end 81 toward an opening at another end 82. To be specific, the optical path tube 80 is tube-shaped, and has the one end 81 that is open and the other end 82 that is open. If the optical path tube 80 is tube-shaped with a diameter of the opening at the other end 82 being greater than a diameter of the opening at the one end 81, the optical path tube 80 may include a portion that is not cone-shaped or truncated cone-shaped. The optical path tube 80 is tube-shaped and has the one end 81 that is open and the other end 82 that is open, and the optical path tube 80 may be tube-shaped increasing in diameter from the opening at the one end 81 toward the opening at the other end 82, with the diameter of the opening at the other end 82 being greater than the diameter of the opening at the one end 81.

The one end 81 of the optical path tube 80 is opposite the target material 11. The one end 81 of the optical path tube 80 may be located in a space on the side at which the plasma forming area is disposed relative to the debris shield 93. That is, the optical path tube 80 may be disposed so as to pass through the debris shield 93. Alternatively, the one end 81 of the optical path tube 80 may be connected to the debris shield 93. The outer cover 241 and the debris shield 93 separate the exhaust space 243 where the target material 11 is disposed and the optical path space 46 where the transmissive member 70 is disposed.

The other end 82 of the optical path tube 80 protrudes into a space on a side at which the transmissive member 70 is disposed relative to the debris shield 93. The other end 82 of the optical path tube 80 may be disposed so as to be opposite the transmissive member 70. Alternatively, the optical path tube 80 may be disposed so that an interior thereof includes the transmissive member 70 (for example, at least one of a glass plate 70a and a focus lens 70b).

A gas intake part 83 of the optical path tube 80 is formed in the optical path tube 80 on the side at which the transmissive member 70 is disposed relative to the debris shield 93. The purge gas 44 taken in from the gas intake part 83 is ejected from the one end 81 of the optical path tube 80 toward the target material 11, and is discharged from the outlet 242 via the exhaust space 243.

The transmissive member 70 is disposed so as to cover the optical path tube 80. For example, the transmissive member 70 may be disposed so as to cover the other end 82 of the optical path tube 80, but may also be disposed in the interior of the optical path tube 80. The transmissive member 70 transmits the laser beam 13. The transmissive member 70 may be, for example, the focus lens 70b that focuses the laser beam 13, or may be the glass plate 70a. Note that the transmissive member 70 is not limited to the focus lens 70b and glass plate 70a, but may be any other optical member as long as the transmissive member 70 can transmit the laser beam 13.

Next, an effect exhibited by the light source apparatus 2 according to Embodiment 1 will be described. When the second outlet 55 is not provided in the optical path tube 50, a vortex or the like may occur and the flow of the purge gas 44 may not be smooth anymore. In this case, a concern is that the purge gas 44 accumulates on the side at which the one end 51 of the optical path tube 50 is disposed, debris cannot be sufficiently prevented from depositing on the filter 60, and the amount of the EUV light 15 extracted from the light source apparatus 2 decreases.

In Embodiment 1, the flow of the purge gas 44 can be made uniform and smooth across the entire cross-section of the optical path tube 50, by providing the second outlet 55 around an outer circumference of the optical path tube 50 in addition to the first outlet 54, thereby further suppressing the deposition of debris on the filter 60. Therefore, the decrease in the amount of the EUV light 15 extracted from the light source apparatus 2 can be suppressed.

### Modified Example 1

In FIG. 1, the first outlet 54 and the second outlet 55 are provided in the optical path tube 50, but a first outlet and a second outlet may be provided in the optical path tube 80. In this case, the optical path tube 80 may pass through the outer cover 241 or be connected to the outer cover 241.

### Modified Example 2

The light source apparatus 2 may not include the exhaust case 240. In this case, the first outlet 54 discharges the purge gas 44 on the side at which the plasma forming area is disposed relative to the debris shield 93, with a space between the opening (one end) 91 and the debris shield 93 as the first outlet 54 for example. That is, the debris shield 93 may serve as the outer cover 241.

### Embodiment 2

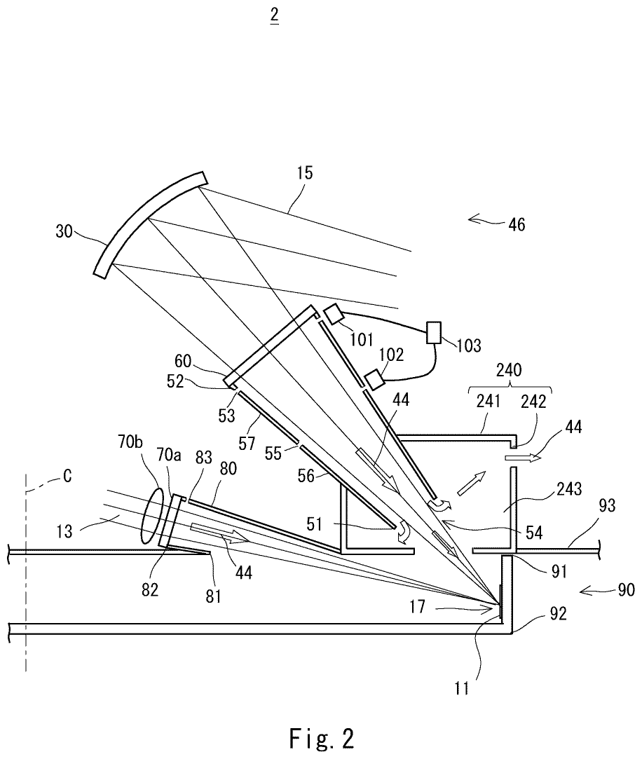

Embodiment 2 is a modified example of Embodiment 1. A light source apparatus 2 according to Embodiment 2 will be described with reference to FIG. 2. In Embodiment 2, a plurality of gas intake parts 53 are provided around the outer circumference of the optical path tube 50. A plurality of second outlets 55 are provided around the outer circumference of the optical path tube 50.

The light source apparatus 2 may include a computer (not shown in the drawing) including a memory, a processor, and the like. Some or all of functions of a control unit 101, a control unit 102, and an acquisition unit 103 described below may be realized by the processor executing a program stored in the memory.

The light source apparatus 2 includes the control unit 101 that adjusts the intake amount of the purge gas 44 from each of the gas intake parts 53 and the control unit 102 that adjusts a discharge amount from each of the second outlets 55. The control unit 101 may, for example, adjust a size of an intake port through which the purge gas 44 is taken in, and adjust a pressure of the purge gas 44 taken in. Adjusting the pressure of the purge gas 44 taken in may include setting the pressure of the purge gas 44 taken in from a specific intake port to zero. The control unit 102 may, for example, adjust a size of the second outlet 55. With this, the control unit 102 may adjust the discharge amount from the second outlet 55. Adjusting the discharge amount may include setting the discharge amount from a specific second outlet 55 to zero.

The light source apparatus 2 may include the acquisition unit 103. The acquisition unit 103 acquires information relating to a contaminated area of the filter 60. The acquisition unit 103 may, for example, image the filter 60 with a camera and acquire the information relating to the contaminated area based on a captured image. Alternatively, the acquisition unit 103 can also acquire the information relating to the contaminated area based on a light intensity distribution of the EUV light 15 extracted from the light source apparatus 2.

In this case, the control unit 101 controls the intake amount of the purge gas 44 at a specific gas intake part 53 among the plurality of gas intake parts 53, based on the information acquired by the acquisition unit 103. The control unit 101 may, for example, increase the intake amount of the purge gas 44 from a specific gas intake part 53 corresponding to the contaminated area.

The control unit 102 controls the discharge amount of the purge gas 44 from a specific second outlet 55 among the plurality of second outlets 55, based on the information acquired by the acquisition unit 103. The control unit 102 may, for example, decrease the discharge amount of the purge gas 44 from a specific second outlet 55 corresponding to the contaminated area.

Embodiment 2 facilitates the smooth flow of the purge gas 44 in the optical path tube 50. Moreover, the intake amount or the discharge amount of the purge gas 44 can be changed in accordance with a contamination condition of the filter 60.

### Embodiment 3

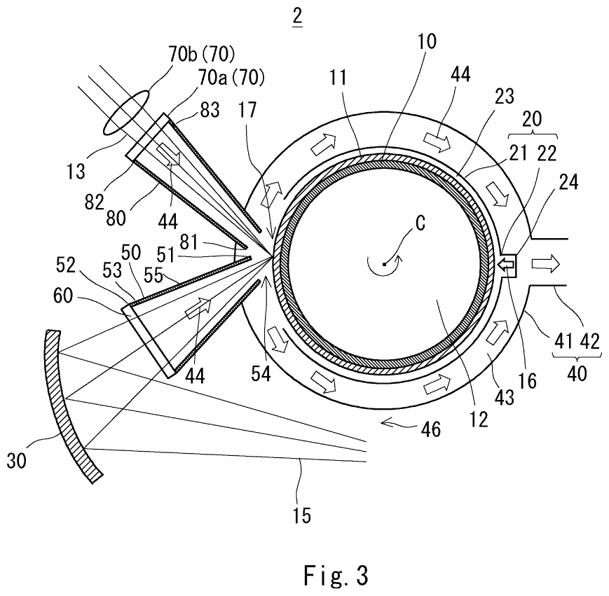

Embodiment 3 is a modified example of Embodiment 1. In Embodiment 3, the target material 11 is solidified on a front surface of a drum 10 instead of being disposed in the interior of the crucible 90. As shown in FIG. 3, a light source apparatus 2 according to Embodiment 3 includes the drum 10, the target material 11, a supply case 20, the collector mirror 30, an exhaust case 40, the optical path tube 50, the filter 60, the transmissive member 70, and the optical path tube 80. A configuration of the collector mirror 30, the optical path tube 50, the filter 60, the transmissive member 70, and the optical path tube 80 in the light source apparatus 2 of Embodiment 3 is the same as a configuration in the light source apparatus 2 of Embodiment 1.

The drum 10 is cylinder-shaped and has a central axis C. The drum 10 rotates about the central axis C as a rotation axis.

The drum 10 includes, for example, copper as a material thereof. A coolant 12 such as liquid nitrogen is supplied to an interior of the drum 10. Thus, the drum 10 is cooled so that the target material 11 solidifies on the front surface. Note that the material of the drum 10 is not limited to copper, but may include any other material as long as a temperature of the front surface of the drum 10 can be maintained equal to or lower than a coagulation point of the target material 11.

The target material 11 generates the EUV light 15 as well as plasma 14, by being irradiated with the laser beam 13. The target material 11 is formed on the front surface of the drum 10. The target material 11 includes, for example, xenon (Xe).

The supply case 20 has a housing 21 and a supply port 22. The housing 21 covers the drum 10. The housing 21 is, for example, cylinder-shaped with a hollow interior. The drum 10 is disposed in the interior of the housing 21. The drum 10 rotates in the interior of the housing 21. A portion of the housing 21 opposite the irradiation position 17 of the laser beam 13 is open. Therefore, the housing 21 may cover the target material 11 except for the irradiation position 17 of the laser beam 13. The housing 21 forms a space on the side at which the target material 11 is disposed relative to the housing 21. The space formed on the side at which the target material 11 is disposed relative to the housing 21 is referred to as a supply space 23.

The supply port 22 communicates with the supply space 23. The supply port 22 is connected to a supply unit 24 of gas 16 of the target material 11. The supply unit 24 supplies the gas 16 of the target material 11 to the supply space 23 via the supply port 22. The gas 16 of the target material 11 supplied from the supply port 22 forms the target material 11, by solidifying on the front surface of the drum 10.

The target material 11 solidified on the front surface of the drum 10 is irradiated with the laser beam 13. This produces plasma from the target material 11. Thus, the EUV light 15 can be generated from the produced plasma.

The exhaust case 40 includes an outer cover 41 and an outlet 42. The outer cover 41 is disposed between the target material 11 and the collector mirror 30. To be specific, the outer cover 41 includes a portion disposed between the target material 11 and the collector mirror 30. The outer cover 41 may cover the supply case 20. In Embodiment 3, the outer cover 41 is cylinder-shaped with a hollow interior. The supply case 20 is disposed in the interior of the outer cover 41. The outer cover 41 forms a space on the side at which the target material 11 is disposed relative to the outer cover 41. The space formed on the side at which the target material 11 is disposed relative to the outer cover 41 is referred to as an exhaust space 43.

The one end 51 of the optical path tube 50 protrudes into the exhaust space 43 on the side at which the target material 11 is disposed relative to the outer cover 41, or is connected to the outer cover 41. The other end 52 of the optical path tube 50 protrudes into a space on the side at which the collector mirror 30 is disposed relative to the outer cover 41. The space formed on the side at which the collector mirror 30 is disposed relative to the outer cover 41 is referred to as the optical path space 46. The exhaust space 43 where the target material 11 is disposed and the optical path space 46 where the collector mirror 30 is disposed are connected by the optical path tube 50. The outer cover 41 separates the exhaust space 43 where the target material 11 is disposed and the optical path space 46 where the collector mirror 30 is disposed.

The opening on the side at which the one end 51 of the optical path tube 50 is disposed functions as the first outlet 54. The first outlet 54 discharges the purge gas 44 on the side at which the plasma forming area is disposed relative to the outer cover 41. The second outlet 55 provided in the lateral surface of the optical path tube 50 discharges the purge gas 44 on the side at which the collector mirror 30 is disposed relative to the outer cover 41.

The one end 81 of the optical path tube 80 protrudes into the exhaust space 43 on the side at which the target material 11 is disposed relative to the outer cover 41, or is connected to the outer cover 41. The other end 82 of the optical path tube 80 protrudes into the space on the side at which the collector mirror 30 is disposed relative to the outer cover 41. The exhaust space 43 where the target material 11 is disposed and the optical path space 46 where the collector mirror 30 is disposed are connected by the optical path tube 80.

According to Embodiment 3, even when the target material 11 is solidified on the drum 10, the flow of the purge gas 44 can be made smooth and the decrease in the amount of the EUV light 15 can be suppressed.

Although embodiments of the present disclosure have been described above, the present disclosure includes appropriate modifications that do not impair the object and advantages thereof, and is not limited by the above embodiments.

The first, second, and third embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A light source apparatus, comprising:
an optical path tube configured to connect a space on a side at which a mirror is disposed and a space on a side at which a plasma forming area is disposed, the mirror being configured to extract light produced by plasma; and
a filter disposed in the optical path tube and configured to transmit light within at least one wavelength band selected from the light generated by the plasma, wherein
the optical path tube is provided with at least one gas intake part configured to take gas into the optical path tube, the at least one gas intake part being provided on the side at which the plasma forming area is disposed relative to the filter,
the optical path tube includes a first outlet and at least one second outlet configured to guide the gas outside of the optical path tube,
the at least one second outlet is provided on the side at which the plasma forming area is disposed relative to the at least one gas intake part, and on the side at which the mirror is disposed relative to the first outlet,
the first outlet discharges the gas on the side at which the plasma forming area is disposed relative to a cover disposed between the plasma forming area and the mirror, and
the at least one second outlet discharges the gas on the side at which the mirror is disposed relative to the cover, and is provided around an outer circumference of the optical path tube.

2. The light source apparatus according to claim 1, wherein the at least one gas intake part is provided in plurality around the outer circumference of the optical path tube.

3. The light source apparatus according to claim 1, wherein the at least one second outlet is provided in plurality around the outer circumference of the optical path tube.

4. The light source apparatus according to claim 1, wherein at least part of the gas taken in from the at least one gas intake part is blown onto at least a partial area of the filter.

5. The light source apparatus according to claim 1, wherein
the optical path tube comprises a first optical path tube on the side at which the plasma forming area is disposed and a second optical path tube on the side at which the mirror is disposed, and
the at least one second outlet is provided at a connection point between the first optical path tube and the second optical path tube.

6. The light source apparatus according to claim 1, further comprising a control unit configured to control a discharge amount of the gas from the at least one second outlet.

7. The light source apparatus according to claim 1, further comprising:
an acquisition unit configured to acquire a contaminated area of the filter; and
a control unit configured to control, based on the contaminated area, an intake amount of gas at a specific gas intake part among the at least one gas intake part in plurality.

8. The light source apparatus according to claim 1, further comprising:
an acquisition unit configured to acquire a contaminated area of the filter; and
a control unit configured to control, based on the contaminated area, a discharge amount at a specific second outlet among the at least one second outlet in plurality.

9. The light source apparatus according to claim 1, further comprising an exhaust case having a casing that includes the cover,
wherein the exhaust case includes, inside the casing, a region to which impurities contained in the gas adhere,
the first outlet is configured to discharge the gas inside the casing, and
the exhaust case further includes a third outlet configured to discharge the gas that has passed through the region and has a reduced impurity concentration, the gas having been discharged from the first outlet.
